(19) United States
(12) Patent Application Publication
(10) Pub. No.: US 2013/0026658 A1
(43) Pub. Date: Jan. 31, 2013

(54) WAFER LEVEL CHIP SCALE PACKAGE FOR WIRE-BONDING CONNECTION

(71) Applicant: Yen-Ju CHEN, Hukou Shiang (TW)

(72) Inventor: Yen-Ju CHEN, Hukou Shiang (TW)

(21) Appl. No.: 13/193,911

(22) Filed: Jul. 29, 2011

(51) Int. Cl. H01L 23/49; H01L 21/56

(52) U.S. Cl. 257/784; 438/127; 257/E23.024; 257/E21.502

(57) ABSTRACT

Primarily disclosed is a wafer-level chip-scale-package (WLCSP) for wire-bonding connection. A first encapsulating layer is formed over a passivation layer of a chip. An RDL (redistribution wiring layer) is formed on the first encapsulating layer. A plurality of wire-bonding pads are stacked on the wiring terminals of the RDL on the first encapsulating layer. Each wire-bonding pad has a top surface and a sidewall. A surface plated layer completely covers the top surfaces of the wire-bonding pads. A second encapsulating layer is formed over the first encapsulating layer to encapsulate the RDL and the sidewalls of the wire-bonding pads. The openings of the second encapsulating layer are smaller than the top surfaces of the corresponding wire-bonding pads to partially encapsulate the surface plated layer. Accordingly, it can resolve the issue of die crack when wire-bonding on thinned chips.

### FIELD OF THE INVENTION

The present invention relates to a packaging technology of semiconductor devices, and more specifically to a wafer-level chip-scale-package (WLCSP) for wire-bonding connection.

### BACKGROUND OF THE INVENTION

It is well-known that IC circuitry is fabricated in semiconductor chips. As the advance of the fabrication method, chips accommodate more functions or higher density of IC. In the mean time, the chip thickness has become thinner and thinner so that chips are vulnerable for die crack during conventional wire-bonding processes leading to damage and failure of IC chips.

Wafer-level chip-scale-package (WLCSP) is a fast developing and growing packaging technology to complete IC packaging in a wafer form to reduce package dimensions as well as fabrication cost. Flip-chip bonding is normally implemented for board-level connection of a WLCSP. The key components of a WLCSP for flip-chip bonding are redistribution layer (RDL), under bump metallurgy (UBM), and bumps such as solder balls or metal posts.

As shown in FIG. 1, a conventional WLCSP 100 primarily comprises a chip 110, an encapsulating layer 120, a redistribution wiring layer (RDL) 130, and a plurality of solder balls 170. IC circuitry with a plurality of disposed bonding pads 113 are fabricated on the active surface of the chip 110 with at least a passivation layer 112 covering the active surface of the chip 110. The RDL 130 is disposed on the passivation layer 112 with a plurality of terminals 132 similar to pads far away from the corresponding bonding pads 113. An encapsulating. layer 120 is formed over the passivation layer 112 to cover the

RDL 130 with a plurality of openings to expose the terminals 132. The UBM 133 includes a plurality of connecting pads aligned to the openings of the encapsulating layer 120 and connected to the terminals 132. The solder balls 170 are jointed to the UBM 133 and are encapsulated by underfilling material or by a half-cured or B-stage adhesive layer 160. The conventional fabrication of solder balls 170 is to form bumps on the UBM by plating, printing, or ball placement and followed by reflow processes to become solder balls so that the terminals 132 would not experience excessive ball stresses. However, when the solder balls 170 are simply replaced by bonding wires through wire-bonding processes, the wire-bonding forces during wire bonding processes easily causes the thinned die to crack, especially for wire-bonding copper wires or other alloy wires which are harder than Au wires where die crack becomes a serious concern.

### SUMMARY OF THE INVENTION

The main purpose of the present invention is to provide a WLCSP for wire-bonding connection to resolve die crack issues during wire bonding on thin dice. The second purpose of the present invention is to provide a WLCSP for wire-bonding connection to avoid oxidation of exposed wire-bonding pads and electron migration issues.

According to the present invention, a WLCSP for wire-bonding connection is revealed in the present invention, comprising a chip, a first encapsulating layer, a redistribution wiring layer (RDL), a plurality of wire-bonding pads, a surface plated layer, and a second encapsulating layer. The chip has a semiconductor base, a passivation layer on the semiconductor base, and a plurality of bonding pads exposed from the passivation layer. The first encapsulating layer is formed over the passivation layer with a plurality of first opening to expose the bonding pads. The RDL is disposed on the first encapsulating layer with a plurality of terminals extending into the first openings to electrically connect to the bonding pads. The RDL further includes a plurality of second terminals disposed on the first encapsulating layer and electrically connected to the corresponding first terminals. The wire-bonding pads are stacked on the second terminals where each wire-bonding pad has a top surface and a sidewall. The surface plated layer completely covers the top surfaces of the wire-bonding pads. The second encapsulating layer is formed over the first encapsulating layer to encapsulate the RDL and the sidewalls of the wire-bonding pads. The second encapsulating layer has a plurality of second openings aligned to the corresponding wire-bonding pads where the dimension of the second opening is smaller than the dimension of the corresponding top surfaces of the wire-bonding pads to partially encapsulate the surface plated layer.

The WLCSP for wire-bonding connection according to the present invention has the following advantages and effects:
1. Through stacking extra wire-bonding pads on the RDL with two encapsulating layers for encapsulation as a technical mean, die crack issues during wire bonding on thin dice can be resolved.
2. Through two encapsulating layers to encapsulate the wire-bonding pads stacked on the RDL with the openings of the top encapsulating layer smaller than the wire-bonding pads as a technical mean, there is no exposed surface of the wire-bonding pads with the surface plated layer partially encapsulated to avoid oxidation of exposed wire-bonding pads and electron migration issues.

### DESCRIPTION OF THE DRAWINGS

FIG. 1 is a cross-sectional view of a conventional WLCSP for flip-chip bonding.

FIG. 2 is a cross-sectional view of a WLCSP for wire-bonding connection according to the first embodiment of the present invention.

FIG. 3 is a partially enlarged cross-sectional view of the WLCSP for wire-bonding connection according to the first embodiment of the present invention.

FIGS. 4A to 4J are cross-sectional views illuminating the fabrication processes of the WLCSP according to the first embodiment of the present invention.

FIG. 5 is a cross-sectional view of another WLCSP for wire-bonding connection according to the second embodiment of the present invention.

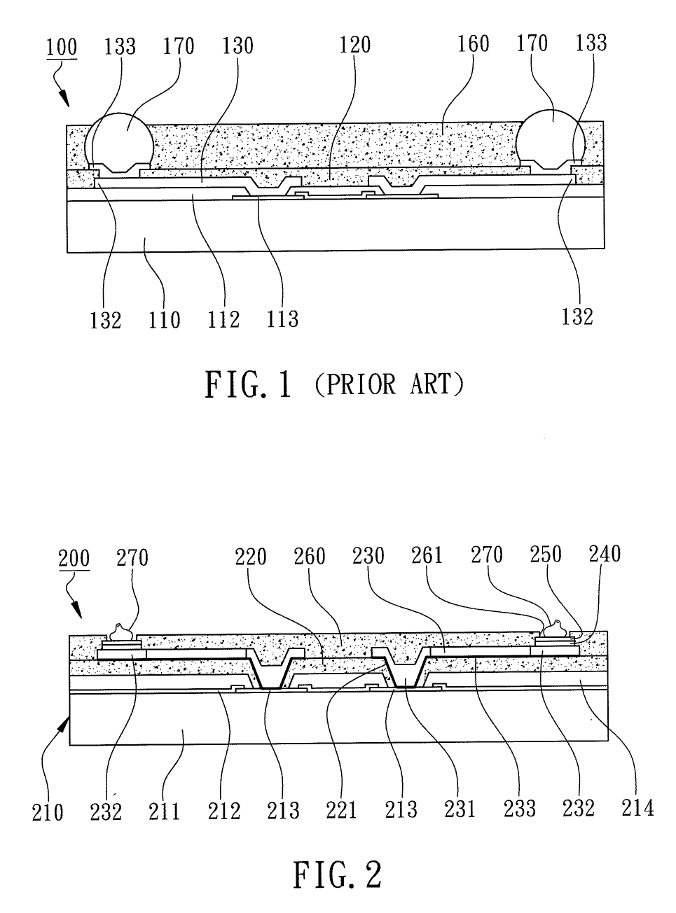

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

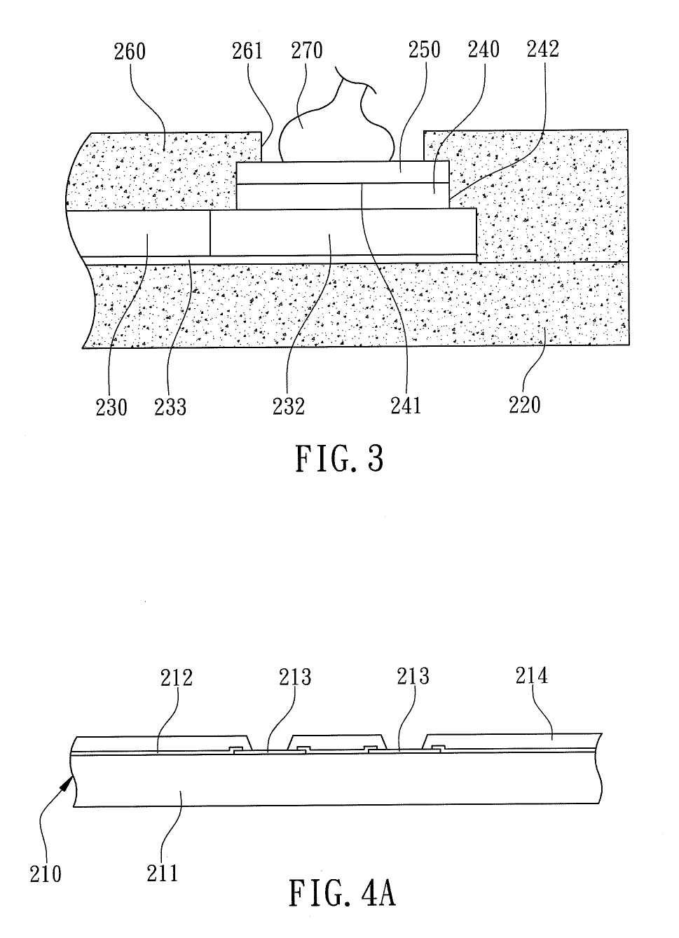

According to the first embodiment of the present invention, a WLCSP 200 for wire-bonding connection is illustrated in FIG. 2 for a cross-sectional view and in FIG. 3 for a partially enlarged cross-sectional view. The WLCSP 200 comprises a chip 210, a first encapsulating layer 220, a redistribution wiring layer (RDL) 230, a plurality of wire-bonding pads 240, a surface plated layer 250, and a second encapsulating layer 260.

As shown in FIG. 2 and FIG. 3, the chip 210 has a semiconductor base 211, at least a passivation layer 212 on the semiconductor base 211, and a plurality of bonding pads 213 exposed from the passivation layer 212. Various IC circuitry is fabricated on the active surface of the chip 210 which is covered by the passivation layer 212 where the bonding pads 213 are external electrical terminals for the IC circuitry. In the present embodiment, the bonding pads 213 are central pads. Moreover, to be more specific, the chip 210 further has a thicker passivation layer 214 disposed between the passivation layer 212 and the first encapsulating layer 220 which is thicker than the passivation layer 212 to increase the overall thickness of the passivation layers. The passivation layer 212 and the thicker passivation layer 214 do not cover the bonding pads 213.

The first encapsulating layer 213 is formed over the passivation layer 212 with a plurality of first openings 221 to expose the bonding pads 213. The first encapsulating layer 220 is made of dielectric and organic material such as polyimide (PI). Normally the thickness of the first encapsulating layer 220 is greater than the one of the passivation layer 212 and may also be greater than the thickness of the thicker passivation layer 214.

The RDL 230 is disposed on the first encapsulating layer 220 where the RDL 230 includes a plurality of traces formed in a wafer form which can be copper or other conductive metals. The RDL 230 further includes a plurality of first terminals 231 extending into the first openings 221 to electrically connect to the corresponding bonding pads 213 and a plurality of second terminals 232 electrically connected to the corresponding first terminals 231 and disposed on the first encapsulating layer 220. The shapes of the second terminals 232 can be like pads far away from the bonding pads 213. The second terminals 232 are electrically connected to the corresponding bonding pads 213 through the first terminals 231 and related traces. In the present embodiment, the second terminals 232 are disposed at the peripheries of the active surface of the chip 210. To be more specific, a UBM 233 is disposed on the bottom of the RDL 230 and adhered to the first encapsulating layer 220 as the seed layer for electrical plating the RDL 230. The UBM layer 233 is fabricated by sputtering or Chemical Vapor Deposition (CVD) adapted from semiconductor fabrication processes to be a thin Au layer or a thin copper layer.

The wire-bonding pads 240 are stacked on top of the second terminals 232 where each wire-bonding pad 240 has a top surface 241 and a sidewall 242. For special attention, the wire-bonding pads 240 are not parts of the RDL 230 but are connecting pads specially fabricated on the RDL 230 to absorb wire-bonding forces where the wire-bonding pads 240 should be made of rigid materials such as copper and the thickness of the wire-bonding pads 240 is preferably greater than the thickness of the RDL 230. Furthermore, the wire-bonding pads 240 are not directly disposed on the passivation layer 212 or 214 where the second terminals 232 and the first encapsulating layer 220 are located between the disposing plane of the wire-bonding pads 240 and the forming plane of the passivation layer 212 to avoid the impact of wire bonding forces on the chip 210 and on the semiconductor base 211. Preferably, the second terminals 232 have a pad dimension larger than the dimension of the wire-bonding pads 240 so that each second terminal 232 has an extruded ring out of the corresponding wire-bonding pad 240. The extruded rings of the second terminal 232 are also located out of the sidewalls 242 of the wire-bonding pads 240 and also encapsulated by the second encapsulating layer 260. That is to say, the wire-bonding pads 240 do not completely cover the second terminals 232 to effectively carry the wire-bonding pads 240 and to maintain the advantage of better encapsulation of the RDL 230 by the second encapsulating layer 260 as shown in FIG. 3.

The surface plated layer 250 completely covers the top surface 241 of the wire-bonding pads 240 to avoid surface oxidation of the wire-bonding pads 240 and to enhance wire bonding strength. The material of the surface plated layer 250 can be Ni/Au or Au and the thickness of the surface plated layer 250 should be smaller than the thickness of the wire-bonding pads 240.

The second encapsulating layer 260 is formed over the first encapsulating layer 220 to encapsulate the RDL 230 and the sidewalls 242 of the wire-bonding pads 240. The second encapsulating layer 260 has a plurality of second openings 261 where the dimension of the second openings 261 is smaller than the dimension of the corresponding top surfaces 241 of the wire-bonding pads 240 to partially encapsulate the surface plated layer 250. The materials of the second encapsulating layer 260 can be the same as the first encapsulating layer 220 such as polyimide. The thickness of the second encapsulating layer 260 is greater than the sum of the thickness of the RDL 230, the thickness of the wire-bonding pads 240, and the thickness of the surface plated layer 250. Preferably, each of the thickness of the first encapsulating layer 220 and the thickness of the second encapsulating layer 260 is greater than the thickness of the passivation layer 212 to enhance the encapsulation and protection of the wire-bonding pads 240.

Furthermore, the WLCSP 200 further comprises one or more wire-bonding joints 270 disposed on the surface plated layer 250 where the wire-bonding joints 270 are ball bonds formed by wire bonding processes but not solder balls formed by reflow processes. In the present embodiment, the wire-bonding joints 270 can be stud bumps which are a plurality of independent parts of a plurality of bonding wires.

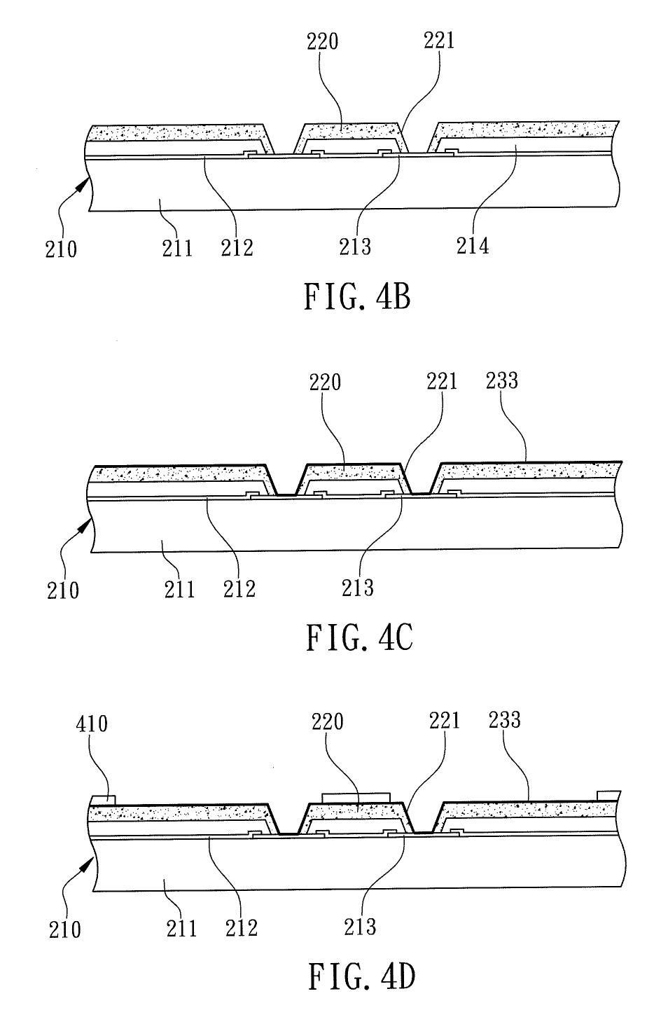

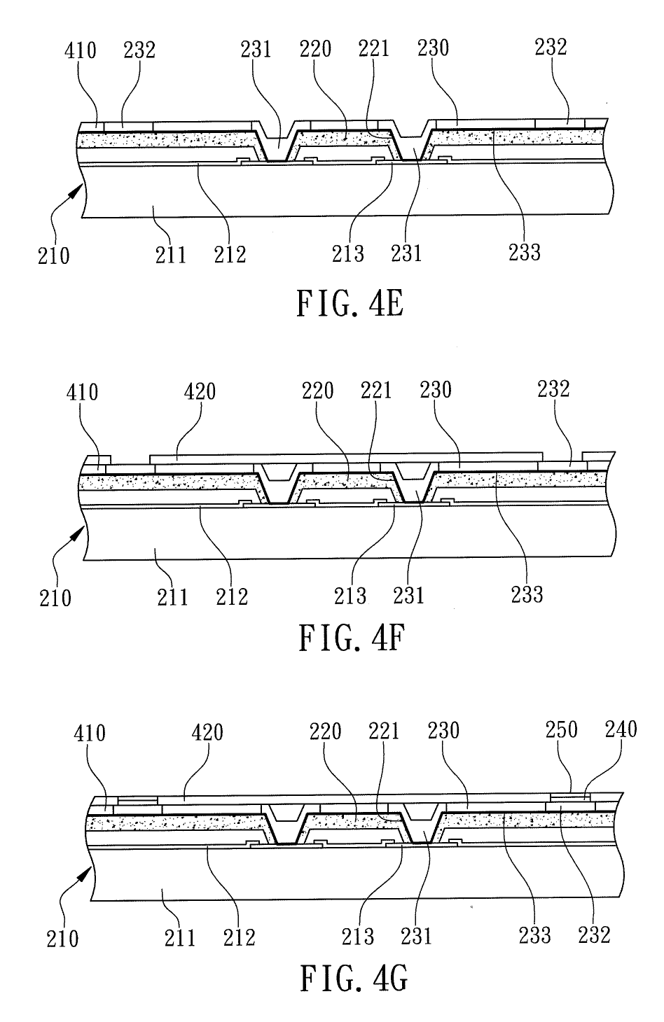

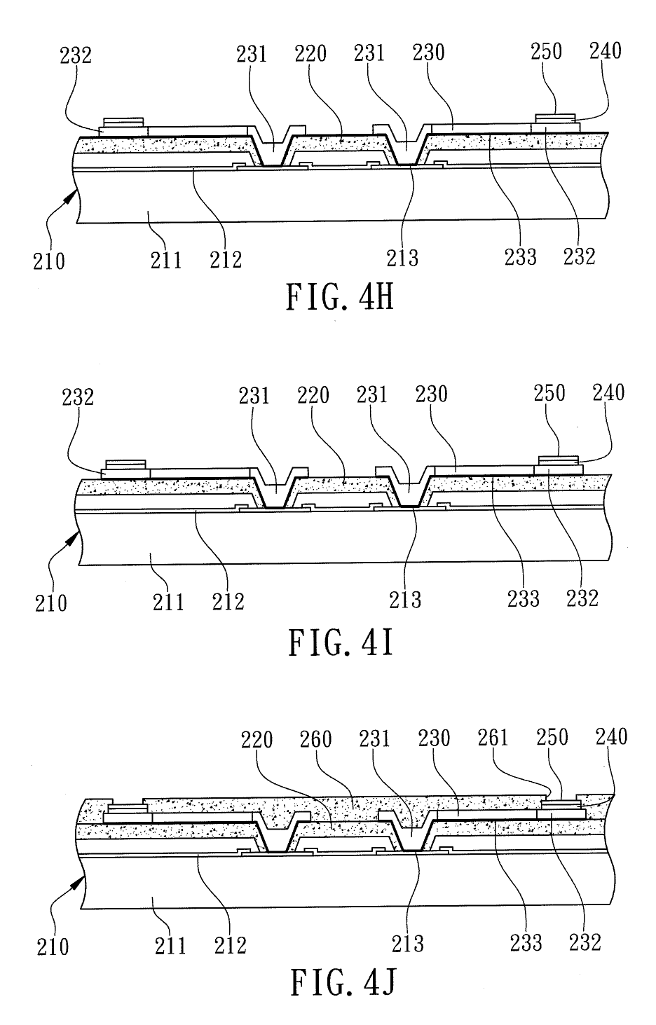

FIGS. 4A to 4J illustrate the fabrication method of the WLCSP 200. Firstly, as shown in FIG. 4A, a chip 210 is provided where the chip 210 is fabricated in a wafer before dicing. The bonding pads 213 of the chip 210 are disposed on the active surface where the passivation layer 212 and the thicker passivation layer 214 are fabricated on the active surface of the wafer. The wafer may go through backside lapping processes to make the thickness of the chip 210 under 10 mils or even as thin as 6 mils. Then, as shown in FIG. 4B, the first encapsulating layer 220 is formed over the passivation layers 212 and 214 by liquid printing or spin coating or by film lamination followed by photolithographic and etching processes to form the first openings 221 on the first encapsulating layer 220 to expose the bonding pads 213. Then, as shown in FIG. 4C, the UBM layer 233 is formed over the first encapsulating layer 220 by sputtering or CVD processes. Then, as shown in FIG. 4D, the first photoresist 410 is formed over the UBM layer 233 by liquid printing or spin coating or by dry film lamination followed by photolithographic processes to define specific opening patterns on the first photoresist 410 to expose the pre-designed area of the RDL 230 on the UBM 233. Then, as shown in FIG. 4E, the UBM layer 233 serves as a seed layer for electrolytic plating the RDL layer 230 in the specific opening patterns of the first photoresist 410 which is disposed on the UBM layer 233 on the first encapsulating layer 220 with the pre-designed RDL patterns. After plating, the RDL 230 including the first terminals 231 and the second terminals 232 is formed. Then, as shown in FIG. 4F, the second photoresist 420 is formed on the first photoresist 410 without stripping the first photoresist 410 and to expose and develop specific pattern openings of the second photoresist 420 through photolithographic processes to expose the pre-defined wire-bonding pad area on the second terminals 232. Then, as shown in FIG. 4G since the RDL 230 is electrically connected to the UBM layer 233 so that the UBM layer 233 can be still used as the common seed layer to continuously plate the wire-bonding pads 240 stacked on the second terminals 232 and the surface plating layer 250 disposed on the top surfaces 241 of the wire-bonding pads 240. Then, as shown in FIG. 4H, the second photoresist 420 and the first photoresist 410 are stripped to expose the UBM layer 233, the RDL 230, the surface plating layer 250 and the sidewalls 242 of the wire-bonding pads 240. Then, as shown in FIG. 4I, the exposed portion of the UBM layer 233 which is not covered by the RDL 230 is removed by etching processes. During this step, even though the materials of the UBM 233 and the RDL are the same such as copper, however, the thickness of the UBM 233 is much thinner than the thickness of the RDL 230. Therefore, under appropriate etching temperature and time with proper controlled etching parameters, the exposed area of the UBM 233 can be etched away but most of the structure of the RDL 230 can be kept intact. Then, the second encapsulating layer 260 is formed over the first encapsulating layer 220 using the same disposing method as the first encapsulating layer 220 to encapsulate the RDL 230 and the sidewalls 242 of the wire-bonding pads 240. The second encapsulating layer 260 has a plurality of second openings 261 aligned to the wire-bonding pads 240 fabricated by photolithography or etching processes where the dimension of the second openings 261 is smaller than the dimension of the top surfaces 241 of the corresponding wire-bonding pads 240 to partially encapsulate the surface plated layer 250. As shown in FIG. 2, one or more wire-bonding joints 270 formed by wire bonding processes can be disposed on the surface plated layer 250. Therefore, the WLCSP according to the present invention can meet the requirements of high product reliability and lower fabrication cost.

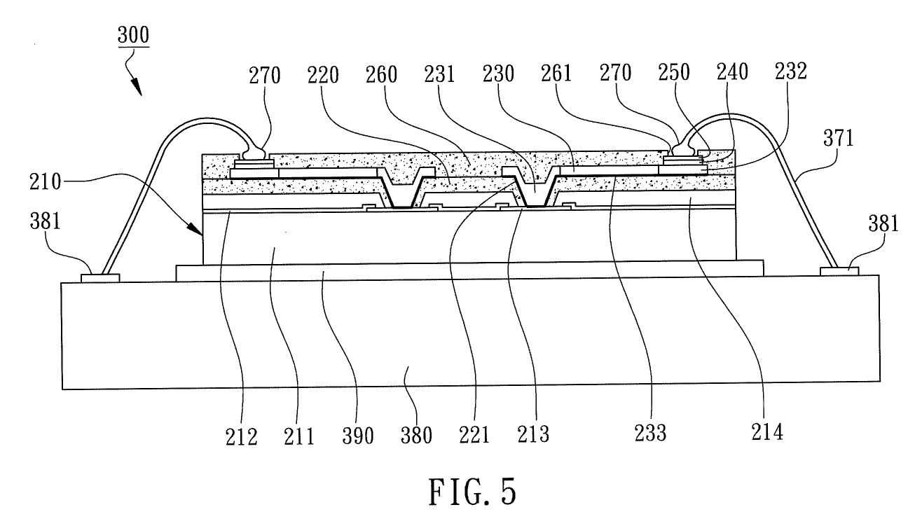

According to the second embodiment of the present invention, another WLCSP 300 is illustrated in FIG. 5 for a cross-sectional view. The same labels and numbers are followed without further description if the components with the same functions described in the WLCSP 300 are the same as the ones described in the first embodiment. The WLCSP 300 comprises a chip 210, a first encapsulating layer 220, a redistribution wiring layer (RDL) 230, a plurality of wire-bonding pads 240, a surface plated layer 250, and a second encapsulating layer 250. The first encapsulating layer 220 is formed over the passivation layer 212 with a plurality of first openings 221 to expose the bonding pads 213. The RDL 230 is disposed on the first encapsulating layer 220 with a plurality of first terminals 231 extending into the first openings 221 to electrically connect to the bonding pads 213 and the RDL 230 further includes a plurality of second terminals 232 disposed on the first encapsulating layer 220 and electrically connected to the corresponding first terminals 231. The wire-bonding pads 240 are stacked on the second terminals 232. The surface plated layer 250 completely covers the top surfaces of the wire-bonding pads 240. The second encapsulating layer 260 is formed over the first encapsulating layer 220 to encapsulate the RDL 230 and the sidewalls of the wire-bonding pads 240 where the second encapsulating layer 260 has a plurality of second openings 261 aligned to the wire-bonding pads 240. The dimension of the second openings 261 is smaller than the top surfaces 241 of the corresponding wire-bonding pads 240 to partially encapsulate the surface plated layer 250. The WLCSP 300 further comprises one or more wire-bonding joints 270 disposed on the surface plated layer 250. In the present embodiment, the wire-bonding joints 270 can be one terminals of complete bonding wires 371 where the other terminals of the bonding wires 371 are bonded on a plurality of bonding fingers 381 of a substrate 280. The chip 210 is disposed to the substrate 380 by a die-attaching layer 390. In the present embodiment, the die-attaching layer 390 adheres the back surface of the semiconductor base 211 of the chip 210 to the top surface of the substrate 380 where the substrate 380 can be a printed circuit board.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

1. A wafer level chip scale package for wire-bonding connection comprising:
a chip having a semiconductor base, a passivation layer on the semiconductor base, and a plurality of bonding pads exposed from the passivation layer;
a first encapsulating layer formed over the passivation layer, wherein the first encapsulating layer has a plurality of first openings to expose the bonding pads;
a redistribution wiring layer disposed on the first encapsulating layer, wherein the redistribution wiring layer includes a plurality of first terminals extending into the first openings to electrically connect to the bonding pads and the redistribution wiring layer further includes a plurality of second terminals disposed on the first encapsulating layer and electrically connected to the corresponding first terminals;
a plurality of wire-bonding pads stacked on the second terminals, wherein each wire-bonding pad has a top surface and a sidewall;
a surface plated layer completely covering the top surfaces of the wire-bonding pads; and
a second encapsulating layer formed over the first encapsulating layer to encapsulate the redistribution wiring layer and the sidewalls of the wire-bonding pads, wherein the second encapsulating layer has a plurality of second openings aligned to the wire-bonding pads, wherein the dimension of the second openings is smaller than the dimension of the top surfaces of the corresponding wire-bonding pads to partially encapsulate the surface plated layer.

2. The wafer level chip scale package as claimed in claim 1, further comprising one or more wire-bonding joints disposed on the surface plated layer.

3. The wafer level chip scale package as claimed in claim 2, wherein the wire-bonding joints are one terminals of a plurality of bonding wires and the other terminals of the bonding wires are bonded on a substrate, wherein the chip is disposed on the substrate.

4. The wafer level chip scale package as claimed in claim 2, wherein the wire-bonding joints are stud bonds which are a plurality of independent parts of a plurality of bonding wires.

5. The wafer level chip scale package as claimed in claim 1, wherein the second terminals have a pad dimension larger than the dimension of the wire-bonding pads so that each second terminal has an extruded ring out of the corresponding wire-bonding pad and encapsulated by the second encapsulating layer.

6. The wafer level chip scale package as claimed in claim 1, wherein the thickness of the second encapsulating layer is greater than the sum of the thickness of the redistribution wiring layer, the thickness of the wire-bonding pads, and the thickness of the surface plated layer.

7. The wafer level chip scale package as claimed in claim 1, wherein each of the thickness of the first encapsulating layer and the second encapsulating layer is greater than the thickness of the passivation layer.

8. The wafer level chip scale package as claimed in claim 1, further comprising a UBM layer disposed at a bottom of the redistribution wiring layer and adhered onto the first encapsulating layer.

9-13. (canceled)
